(19) United States
(12) Patent Application Publication
(10) Pub. No.: US 2024/0399713 A1
(43) Pub. Date: Dec. 5, 2024

(54) POLYAMIDE ACID, POLYIMIDE, NON-THERMOPLASTIC POLYIMIDE FILM, MULTI-LAYERED POLYIMIDE FILM, AND METAL-CLAD LAMINATE

(71) Applicant: KANEKA CORPORATION, Osaka (JP)

(72) Inventors: Takahiro Sato, Osaka (JP); Keisuke Oguma, Shiga (JP)

(73) Assignee: KANEKA CORPORATION, Osaka (JP)

(21) Appl. No.: 18/802,303

(22) Filed: Aug. 13, 2024

Related U.S. Application Data
(63) Continuation of application No. PCT/JP2023/004721, filed on Feb. 13, 2023.

(30) Foreign Application Priority Data
Feb. 24, 2022 (JP) 2022-026383

(51) Int. Cl. B32B 15/08; B32B 7/12; B32B 37/12; C08G 73/10

(52) U.S. Cl. CPC B32B 15/08; B32B 7/12; B32B 37/1207; C08G 73/1007; B32B 2037/1215; B32B 2379/08

(57) ABSTRACT

A polyamide acid including tetracarboxylic dianhydride residues and diamine residues is provided. The tetracarboxylic dianhydride residues include a 3,3′,4,4′-biphenyltetracarboxylic dianhydride residue and a 3,3′,4,4′-benzophenonetetracarboxylic dianhydride residue. The diamine residues include a p-phenylenediamine residue and a 1,3-bis(4-aminophenoxy)benzene residue. A multi-layered polyimide film includes a non-thermoplastic polyimide film and an adhesive layer containing a thermoplastic polyimide disposed on at least one surface of the non-thermoplastic polyimide film.

### TECHNICAL FIELD

The present disclosure relates to a polyamide acid, a polyimide, a non-thermoplastic polyimide film, a multi-layered polyimide film, and a metal-clad laminate.

### BACKGROUND

In recent years, demand for flexible printed circuit boards (hereinafter, sometimes referred to as “FPCs”) has been growing with an expansion of demand for electronic products mainly including smartphones, tablet personal computers, notebook personal computers, and the like. Among them, FPCs in which a multi-layered polyimide film including a non-thermoplastic polyimide layer (core layer) and a thermoplastic polyimide layer (adhesive layer) is used as a material are excellent in heat resistance and flexibility, and therefore further growth of demand for these FPCs is expected. A polyimide has heat resistance sufficient to be adaptable to a high-temperature process, and has a relatively small linear expansion coefficient, so that internal stress is less likely to occur. Thus, a polyimide is suitable as a material for FPCs.

Recent high-speed signal transmission in electronic devices is increasing a demand for reduction of the dielectric constant and reduction of the dielectric loss tangent of an electronic substrate material in order to achieve an increase in frequency of an electric signal propagating through a circuit. For suppressing a transmission loss of an electric signal, it is effective to reduce the dielectric constant and the dielectric loss tangent of an electronic substrate material. In recent years as early days of the IoT society, there has been a growing trend toward an increase in frequency, and a substrate material has been desired in which a transmission loss can be suppressed even in a region of 10 GHz or more, for example.

The transmission loss is represented by the following formula using a proportional constant (k), a frequency (f), a dielectric loss tangent (Df), and a relative dielectric constant (Dk), and the dielectric loss tangent contributes to the transmission loss to a greater degree than the relative dielectric constant. Therefore, for reducing the transmission loss, reduction of the dielectric loss tangent is particularly important.

Transmission loss=k×f×Df×(Dk)¹²

As a material used in a circuit substrate adaptable to an increase in frequency, a polyimide film (polyimide layer) that exhibits a low dielectric loss tangent is known (see, for example, Patent Documents 1 to 4).

### PATENT DOCUMENTS

Patent Document 1: Japanese Patent Application Laid-Open Publication No. 2014-526399
Patent Document 2: Japanese Patent Application Laid-Open Publication No. 2009-246201
Patent Document 3: International Publication No. WO 2018/079710
Patent Document 4: International Publication No. WO 2016/159060 However, the techniques described in Patent Documents 1 to 4 still have room for improvement in reduction of the dielectric loss tangent.

### SUMMARY

The present invention has been made in view of the above problems, and one or more embodiments of the present invention provide a polyimide in which the dielectric loss tangent can be reduced, and a polyamide acid as a precursor of the polyimide. One or more embodiments of the present invention further provide a non-thermoplastic polyimide film, a multi-layered polyimide film, and a metal-clad laminate that are produced using the polyimide and the polyamide acid.

An aspect of the present invention is as follows.

[1] A polyamide acid including: tetracarboxylic dianhydride residues; and diamine residues,
the tetracarboxylic dianhydride residues including a 3,3′,4,4′-biphenyltetracarboxylic dianhydride residue and a 3,3′,4,4′-benzophenonetetracarboxylic dianhydride residue,
the diamine residues including a p-phenylenediamine residue and a 1,3-bis(4-aminophenoxy)benzene residue.

[2] The polyamide acid according to [1], in which a content rate of the p-phenylenediamine residue is 75 mol % or more and 95 mol % or less with respect to a total amount of the diamine residues.

[3] The polyamide acid according to [1] or [2], in which
a content rate of the 3,3′,4,4′-biphenyltetracarboxylic dianhydride residue is 55 mol % or more and 85 mol % or less with respect to a total amount of the tetracarboxylic dianhydride residues, and
a content rate of the 3,3′,4,4′-benzophenonetetracarboxylic dianhydride residue is 10 mol % or more and 30 mol % or less with respect to the total amount of the tetracarboxylic dianhydride residues.

[4] The polyamide acid according to [3], in which
the tetracarboxylic dianhydride residues further include a pyromellitic dianhydride residue, and
a content rate of the pyromellitic dianhydride residue is 3 mol % or more and 15 mol % or less with respect to the total amount of the tetracarboxylic dianhydride residues.

[5] A polyimide that is an imidized product of the polyamide acid according to any one of [1] to [4].

[6] A non-thermoplastic polyimide film including the polyimide according to [5].

[7] A multi-layered polyimide film including:
the non-thermoplastic polyimide film according to [6]; and
an adhesive layer disposed on at least one surface of the non-thermoplastic polyimide film, the adhesive layer containing a thermoplastic polyimide.

[8] The multi-layered polyimide film according to [7], in which the adhesive layer is disposed on each of both surfaces of the non-thermoplastic polyimide film.

[9] A metal-clad laminate including:
the multi-layered polyimide film according to [7] or [8]; and
a metal layer disposed on a main surface of at least one of the adhesive layer of the multi-layered polyimide film.

According to one or more embodiments of the present invention, it is possible to provide a polyimide in which the dielectric loss tangent can be reduced, and a polyamide acid as a precursor of the polyimide. Furthermore, according to one or more embodiments of the present invention, it is also possible to provide a non-thermoplastic polyimide film, a multi-layered polyimide film, and a metal-clad laminate that are produced using the polyimide and the polyamide acid.

### BRIEF DESCRIPTION OF THE DRAWINGS

FIG. 1 is a sectional view showing an example of a multi-layered polyimide film according to one or more embodiments of the present invention.

FIG. 2 is a sectional view showing an example of a metal-clad laminate according to one or more embodiments of the present invention.

### DETAILED DESCRIPTION

One or more embodiments of the present invention will be described in detail below, but the present invention is not limited to these embodiments. The academic documents and the patent documents mentioned in the present description are incorporated in the present description by reference in their entirety.

First, terms used in the present description will be described. The term “structural unit” refers to a repeating unit included in a polymer. The term “polyamide acid” refers to a polymer including a structural unit represented by the following general formula (1) (hereinafter, sometimes referred to as “structural unit (1)”).

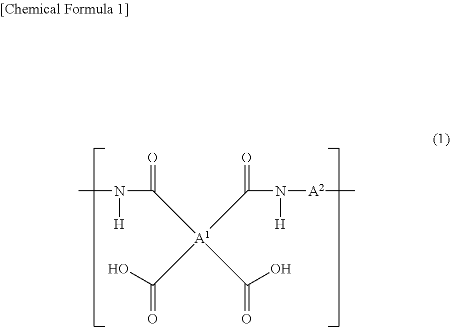

In the general formula (1), A¹ represents a tetracarboxylic dianhydride residue (tetravalent organic group derived from tetracarboxylic dianhydride), and A² represents a diamine residue (divalent organic group derived from a diamine).

The content rate of the structural unit (1) with respect to all of the structural units included in the polyamide acid is, for example, 50 mol % or more and 100 mol % or less, preferably 60 mol % or more and 100 mol % or less, more preferably 70 mol % or more and 100 mol % or less, still more preferably 80 mol % or more and 100 mol % or less, and still even more preferably 90 mol % or more and 100 mol % or less, and may be 100 mol %.

The “linear expansion coefficient” is a coefficient of linear expansion during temperature rise from 50° C. to 250° C. unless otherwise specified. The method for measuring the linear expansion coefficient is identical or similar to the method in examples described below.

The “relative dielectric constant” is a relative dielectric constant at a frequency of 10 GHz, a temperature of 23° C., and a relative humidity of 50%. The “dielectric loss tangent” is a dielectric loss tangent at a frequency of 10 GHz, a temperature of 23° C., and a relative humidity of 50%. The methods for measuring the relative dielectric constant and the dielectric loss tangent are identical or similar to the methods in examples described below.

The term “non-thermoplastic polyimide” refers to a polyimide that retains a film shape (flat film shape) when fixed in a film state to a metallic fixation frame and heated at a heating temperature of 380° C. for 1 minute. The term “thermoplastic polyimide” refers to a polyimide that does not retain a film shape when fixed in a film state to a metallic fixation frame and heated at a heating temperature of 380° C. for 1 minute.

The term “main surface” of a layered material (more specifically, non-thermoplastic polyimide film, adhesive layer, multi-layered polyimide film, metal layer, or the like) refers to a surface orthogonal to the thickness direction of the layered material.

Hereinafter, the name of a compound may be followed by the term “-based” to collectively refer to the compound and its derivatives. The tetracarboxylic dianhydride may be referred to as “acid dianhydride”. The non-thermoplastic polyimide contained in the non-thermoplastic polyimide film may be simply referred to as “non-thermoplastic polyimide”. The thermoplastic polyimide contained in the adhesive layer may be simply referred to as “thermoplastic polyimide”.

Unless otherwise specified, the components, the functional groups, and the like shown in the present description may be used alone, or in combination of two or more kinds thereof.

In the drawings that are referred to in the following description, the constituent elements are schematically shown for easy understanding, and the size, the number, the shape, and the like of each illustrated constituent element may be different from the actual counterparts for convenience of preparing the drawings. For convenience of description, in the drawings described below, the same constituent part as in a previously described drawing will be given the same reference sign as in the previously described drawing, and the description of the constituent part may be omitted.

### First Embodiment: Polyamide Acid

A polyamide acid according to a first embodiment of the present invention (hereinafter, sometimes referred to as “polyamide acid (1)”) has tetracarboxylic dianhydride residues and diamine residues. The tetracarboxylic dianhydride residues include a 3,3′,4,4′-biphenyltetracarboxylic dianhydride residue and a 3,3′,4,4′-benzophenonetetracarboxylic dianhydride residue. That is, the polyamide acid (1) includes the 3,3′,4,4′-biphenyltetracarboxylic dianhydride residue and the 3,3′,4,4′-benzophenonetetracarboxylic dianhydride residue as the tetracarboxylic dianhydride residues. The diamine residues include a p-phenylenediamine residue and a 1,3-bis(4-aminophenoxy)benzene residue. That is, the polyamide acid (1) includes the p-phenylenediamine residue and the 1,3-bis(4-aminophenoxy)benzene residue as the diamine residues.

Hereinafter, 3,3′,4,4′-biphenyltetracarboxylic dianhydride may be referred to as “BPDA”. 3,3′,4,4′-Benzophenonetetracarboxylic dianhydride may be referred to as “BTDA”. p-Phenylenediamine may be referred to as “PDA”. 1,3-Bis(4-aminophenoxy)benzene may be referred to as “TPE-R”. Pyromellitic dianhydride may be referred to as “PMDA”. 4,4′-Oxydiphthalic anhydride may be referred to as “ODPA”.

According to the polyimide obtained from the polyamide acid (1), the dielectric loss tangent can be reduced. The reason for this is presumed as follows.

The polyamide acid (1) includes the BPDA residue and the BTDA residue as the tetracarboxylic dianhydride residues, and includes the PDA residue and the TPE-R residue as the diamine residues. Thus, the polyamide acid (1) includes a residue having a rigid structure and a residue having a bend structure, and therefore the polyimide obtained from the polyamide acid (1) has a stable higher order structure. Therefore, according to the polyimide obtained from the polyamide acid (1), the dielectric loss tangent can be reduced.

The polyamide acid (1) may have another acid dianhydride residue in addition to the BPDA residue and the BTDA residue. Examples of the acid dianhydride (monomer) for formation of another acid dianhydride residue (an acid dianhydride residue other than the BPDA residue and the BTDA residue) include PMDA, ODPA, 2,3,6,7-naphthalenetetracarboxylic dianhydride, 1,2,5,6-naphthalenetetracarboxylic dianhydride, 2,2′,3,3′-biphenyltetracarboxylic dianhydride, 2,2′,3,3′-benzophenonetetracarboxylic dianhydride, 3,4′-oxydiphthalic anhydride, 2,2-bis(3,4-dicarboxyphenyl) propane dianhydride, 3,4,9,10-perylenetetracarboxylic dianhydride, 1,1-bis(2,3-dicarboxyphenyl) ethane dianhydride, 1,1-bis(3,4-dicarboxyphenyl) ethane dianhydride, ethylenebis(trimellitic acid monoester acid anhydride), bisphenol A bis(trimellitic acid monoester acid anhydride), and derivatives thereof.

Another acid dianhydride residue is preferably a PMDA residue for obtaining a polyimide in which the dielectric loss tangent can be further reduced while the heat resistance is enhanced.

For obtaining a polyimide in which the dielectric loss tangent can be further reduced, the total content rate of the BPDA residue and the BTDA residue with respect to all of the acid dianhydride residues included in the polyamide acid (1) is preferably 80 mol % or more, and may be 85 mol % or more, 88 mol % or more, 90 mol % or more, 92 mol % or more, or 100 mol %.

In the case of using a PMDA residue as another acid dianhydride residue, for obtaining a polyimide in which the dielectric loss tangent can be further reduced while the heat resistance is enhanced, the total content rate of the BPDA residue, the BTDA residue, and the PMDA residue with respect to all of the acid dianhydride residues included in the polyamide acid (1) is preferably 85 mol % or more, and more preferably 90 mol % or more, and may be 100 mol %.

For obtaining a polyimide in which the dielectric loss tangent can be further reduced, the content rate of the BPDA residue with respect to all of the acid dianhydride residues included in the polyamide acid (1) is preferably 55 mol % or more and 85 mol % or less, more preferably 60 mol % or more and 80 mol % or less, and still more preferably 65 mol % or more and 78 mol % or less.

For obtaining a polyimide in which the dielectric loss tangent can be further reduced, the content rate of the BTDA residue with respect to all of the acid dianhydride residues included in the polyamide acid (1) is preferably 10 mol % or more and 30 mol % or less, and more preferably 15 mol % or more and 25 mol % or less.

For obtaining a polyimide in which the dielectric loss tangent can be further reduced while the heat resistance is enhanced, the content rate of the PMDA residue with respect to all of the acid dianhydride residues included in the polyamide acid (1) is preferably 3 mol % or more and 15 mol % or less, and more preferably 5 mol % or more and 12 mol % or less.

The polyamide acid (1) may have another diamine residue in addition to the PDA residue and the TPE-R residue. Examples of the diamine (monomer) for formation of another diamine residue (a diamine residue other than the PDA residue and the TPE-R residue) include 1,4-bis(4-aminophenoxy)benzene, 4,4′-diaminodiphenylpropane, 4,4′-diaminodiphenylmethane, 4,4′-diaminodiphenyl sulfide, 3,3′-diaminodiphenyl sulfone, 4,4′-diaminodiphenyl sulfone, 3,3′-diaminodiphenyl ether, 3,4′-diaminodiphenyl ether, 1,5-diaminonaphthalene, 4,4′-diaminodiphenyldiethylsilane, 4,4′-diaminodiphenylsilane, 4,4′-diaminodiphenylethylphosphine oxide, 4,4′-diaminodiphenyl N-methylamine, 4,4′-diaminodiphenyl N-phenylamine, 1,3-diaminobenzene, 1,2-diaminobenzene, and derivatives thereof.

For obtaining a polyimide in which the dielectric loss tangent can be further reduced, the total content rate of the PDA residue and the TPE-R residue with respect to all of the diamine residues included in the polyamide acid (1) is preferably 85 mol % or more, more preferably 90 mol % or more, and still more preferably 95 mol % or more, and may be 100 mol %.

For obtaining a polyimide in which the dielectric loss tangent can be further reduced, the content rate of the PDA residue with respect to all of the diamine residues included in the polyamide acid (1) is preferably 75 mol % or more and 95 mol % or less, more preferably 80 mol % or more and 95 mol % or less, and still more preferably 80 mol % or more and 90 mol % or less.

For obtaining a polyimide in which the dielectric loss tangent can be further reduced, the content rate of the TPE-R residue with respect to all of the diamine residues included in the polyamide acid (1) is preferably 2 mol % or more and 20 mol % or less, more preferably 5 mol % or more and 18 mol % or less, and still more preferably 10 mol % or more and 18 mol % or less.

For obtaining a polyimide in which the dielectric loss tangent can be further reduced, the substance amount ratio obtained by dividing the total substance amount of the acid dianhydride residues included in the polyamide acid (1) by the total substance amount of the diamine residues included in the polyamide acid (1) is preferably 0.95 or more and 1.05 or less, more preferably 0.97 or more and 1.03 or less, and still more preferably 0.99 or more and 1.01 or less. If the substance amount ratio is adjusted to 0.95 or more and 1.05 or less, the substance amount ratio obtained by dividing the total substance amount of the acid dianhydride residues included in the resulting polyimide by the total substance amount of the diamine residues included in the polyimide is 0.95 or more and 1.05 or less. An example of the method for synthesizing the polyamide acid (1) will be described below.

For obtaining a polyimide in which the dielectric loss tangent can be further reduced and the linear expansion coefficient is small, the polyamide acid (1) preferably satisfies the following condition 1, more preferably satisfies the following condition 2, still more preferably satisfies the following condition 3, and particularly preferably satisfies the following condition 4.

Condition 1: The content rate of the BPDA residue with respect to all of the acid dianhydride residues included the polyamide acid (1) is 55 mol % or more and 85 mol % or less, and the content rate of the BTDA residue with respect to all of the acid dianhydride residues included in the polyamide acid (1) is 10 mol % or more and 30 mol % or less.

Condition 2: The condition 1 is satisfied, and the polyamide acid (1) further has a PMDA residue as an acid dianhydride residue.

Condition 3: The condition 2 is satisfied, and the content rate of the PMDA residue with respect to all of the acid dianhydride residues included in the polyamide acid (1) is 3 mol % or more and 15 mol % or less.

Condition 4: The condition 3 is satisfied, and the content rate of the PDA residue with respect to all of the diamine residues included in the polyamide acid (1) is 75 mol % or more and 95 mol % or less.

### Second Embodiment: Polyimide

Next, a polyimide according to a second embodiment of the present invention will be described. The polyimide according to the second embodiment is an imidized product of the above-described polyamide acid (1). The polyimide according to the second embodiment can be obtained by a known method, and the method for producing the polyimide is not particularly limited. An example of the method for imidizing the polyamide acid (1) will be described below.

### Third Embodiment: Non-Thermoplastic Polyimide Film

Next, a non-thermoplastic polyimide film according to a third embodiment of the present invention will be described. The non-thermoplastic polyimide film according to the third embodiment is a non-thermoplastic polyimide film containing the polyimide according to the second embodiment (specifically, the non-thermoplastic polyimide as an imidized product of the polyamide acid (1)).

The non-thermoplastic polyimide film according to the third embodiment may contain a component (additive) other than the non-thermoplastic polyimide. As the additive, for example, a dye, a surfactant, a leveling agent, a plasticizer, silicone, a filler, a sensitizer, or the like can be used. The content rate of the non-thermoplastic polyimide in the non-thermoplastic polyimide film is, for example, 70 wt % or more, preferably 80 wt % or more, and more preferably 90 wt % or more, and may be 100 wt % with respect to the total amount of the non-thermoplastic polyimide film.

### [Method for Producing Non-Thermoplastic Polyimide Film]

The non-thermoplastic polyimide contained in the non-thermoplastic polyimide film is obtained by imidizing the polyamide acid (1) as a precursor of the non-thermoplastic polyimide.

As the method for producing (synthesizing) the polyamide acid (1), any of known methods and combinations thereof can be used. In production of the polyamide acid (1), normally, diamines and tetracarboxylic dianhydrides are reacted in an organic solvent. The substance amount of the diamines and the substance amount of the tetracarboxylic dianhydrides in the reaction are preferably substantially the same. When the polyamide acid (1) is synthesized using the diamines and the tetracarboxylic dianhydrides, the desired polyamide acid (1) (polymer of the diamines and the tetracarboxylic dianhydrides) can be obtained by adjusting the substance amount of each diamine and the substance amount of each tetracarboxylic dianhydride. The molar fraction of each residue in the polyamide acid (1) is equal to, for example, the molar fraction of each monomer (each of the diamines and the tetracarboxylic dianhydrides) used for synthesis of the polyamide acid (1). The temperature condition for the reaction of the diamines with the tetracarboxylic dianhydrides, that is, the synthesis reaction of the polyamide acid (1) is not particularly limited, and is, for example, in the range of 10° C. or higher and 150° C. or lower. The time for the synthesis reaction of the polyamide acid (1) is, for example, in the range of 10 minutes or more and 30 hours or less. In the present embodiment, any method for adding a monomer may be used for production of the polyamide acid (1). Examples of the typical method for producing the polyamide acid (1) include the following methods.

Examples of the method for producing the polyamide acid (1) include a method in which polymerization is performed by the following steps (A-a) and (A-b) (hereinafter, sometimes referred to as “polymerization method A”).
(A-a): The step of reacting a diamine with an acid dianhydride in an organic solvent with the diamine being in excess to obtain a prepolymer having an amino group at both ends.
(A-b): The step of adding a diamine different in structure from that used in the step (A-a), and further adding an acid dianhydride different in structure from that used in the step (A-a) so that the amount of the diamines and the amount of the acid dianhydrides in the entire steps are substantially equal to each other in terms of mol, and thus performing polymerization.

Examples of the method for producing the polyamide acid (1) also include a method in which polymerization is performed by the following steps (B-a) and (B-b) (hereinafter, sometimes referred to as “polymerization method B”).
(B-a): The step of reacting a diamine with an acid dianhydride in an organic solvent with the acid dianhydride being in excess to obtain a prepolymer having an acid anhydride group at both ends.
(B-b): The step of adding an acid dianhydride different in structure from that used in the step (B-a), and further adding a diamine different in structure from that used in the step (B-a) so that the amount of the diamines and the amount of the acid dianhydrides in the entire steps are substantially equal to each other in terms of mol, and thus performing polymerization.

A polymerization method in which the order of addition is set so that a specific diamine or a specific acid dianhydride selectively reacts with any or a specific diamine or any or a specific acid dianhydride (for example, the polymerization method A or polymerization method B described above) is referred to as sequence polymerization in the present description. In contrast, a polymerization method in which the order of addition of a diamine and an acid dianhydride is not set (polymerization method in which monomers freely react with each other) is referred to as random polymerization in the present description. In a case where sequence polymerization is performed in two steps as in the polymerization method A and the polymerization method B, the earlier step (the step (A-a), the step (B-a), or the like) is referred to as “first sequence polymerization step”, and the latter step (the step (A-b), the step (B-b), or the like) is referred to as “second sequence polymerization step” in the present description.

In one or more embodiments, for obtaining the non-thermoplastic polyimide film in which the dielectric loss tangent can be further reduced, the method for polymerization of the polyamide acid (1) is preferably sequence polymerization.

For obtaining the non-thermoplastic polyimide, a method may be adopted in which the non-thermoplastic polyimide is obtained from a polyamide acid solution containing the polyamide acid (1) and an organic solvent. Examples of the organic solvent usable in the polyamide acid solution include urea-based solvents such as tetramethylurea and N,N-dimethylethylurea; sulfoxide-based solvents such as dimethyl sulfoxide; sulfone-based solvents such as diphenyl sulfone and tetramethyl sulfone; amide-based solvents such as N,N-dimethylacetamide, N,N-dimethylformamide (hereinafter, sometimes referred to as “DMF”), N,N-diethylacetamide, N-methyl-2-pyrrolidone, and hexamethylphosphoric triamide; ester-based solvents such as y-butyrolactone; alkyl halide-based solvents such as chloroform and methylene chloride; aromatic hydrocarbon-based solvents such as benzene and toluene; phenol-based solvents such as phenol and cresol; ketone-based solvents such as cyclopentanone; and ether-based solvents such as tetrahydrofuran, 1,3-dioxolane, 1,4-dioxane, dimethyl ether, diethyl ether, diethylene glycol diethyl ether, diethylene glycol dimethyl ether, and p-cresol methyl ether. These solvents are normally used singly, and if necessary, may be appropriately used in combination of two or more kinds thereof. In the case of obtaining the polyamide acid (1) by the above-described polymerization method, the reaction solution (solution after reaction) itself may be a polyamide acid solution used for obtaining the non-thermoplastic polyimide. In this case, the organic solvent in the polyamide acid solution is the organic solvent used in the reaction in the polymerization method. Alternatively, the solid polyamide acid (1) obtained by removing the solvent from the reaction solution may be dissolved in an organic solvent to prepare a polyamide acid solution.

To the polyamide acid solution, an additive may be added such as a dye, a surfactant, a leveling agent, a plasticizer, silicone, a filler, or a sensitizer. The concentration of the polyamide acid (1) in the polyamide acid solution is not particularly limited, and is, for example, 5 wt % or more and 35 wt % or less, and preferably 8 wt % or more and 30 wt % or less with respect to the total amount of the polyamide acid solution. If the concentration of the polyamide acid (1) is 5 wt % or more and 35 wt % or less, an appropriate molecular weight and an appropriate solution viscosity are obtained.

The method for obtaining the non-thermoplastic polyimide film using the polyamide acid solution is not particularly limited, and various known methods can be applied. Examples thereof include a method in which the non-thermoplastic polyimide film is obtained through the following steps i) to iii).
Step i): The step of applying a dope solution containing a polyamide acid solution onto a support to form a coating film.
Step ii): The step of drying the coating film on the support to obtain a polyamide acid film (hereinafter, sometimes referred to as “gel film”) having a self-supporting property, and then peeling off the gel film from the support.
Step iii): The step of heating the gel film to imidize the polyamide acid (1) in the gel film, and thus obtaining a non-thermoplastic polyimide film containing a non-thermoplastic polyimide.

The methods for obtaining the non-thermoplastic polyimide film through the steps i) to iii) are classified broadly into a thermal imidization method and a chemical imidization method. The thermal imidization method is a method in which is a polyamide acid solution is applied as a dope solution onto a support without using a dehydrating and ring-closing agent or the like, and heated to promote imidization. The chemical imidization method is a method in which a solution obtained by adding at least one of a dehydrating and ring-closing agent or a catalyst to a polyamide acid solution is used as a dope solution to accelerate imidization. Either of the methods may be used, and the chemical imidization method is superior in productivity.

As the dehydrating and ring-closing agent, an acid anhydride typified by acetic anhydride is suitably used. As the catalyst, a tertiary amine is suitably used such as an aliphatic tertiary amine, an aromatic tertiary amine, or a heterocyclic tertiary amine (more specifically, isoquinoline or the like). When added to the polyamide acid solution, at least one of the dehydrating and ring-closing agent or the catalyst may be directly added without being dissolved in an organic solvent, or may be dissolved in an organic solvent and then the resulting solution may be added. In the method of direct addition without dissolution in an organic solvent, the reaction may rapidly proceed before diffusion of at least one of the dehydrating and ring-closing agent or the catalyst, resulting in generation of a gel. Therefore, a solution (imidization accelerator) obtained by dissolving at least one of the dehydrating and ring-closing agent or the catalyst in an organic solvent is preferably added to the polyamide acid solution.

The method for applying a dope solution onto a support in the step i) is not particularly limited, and a method using a conventionally known applicator such as a die coater, a Comma Coater (registered trademark), a reverse coater, or a knife coater can be adopted.

As the support to which the dope solution is applied in the step i), a glass plate, an aluminum foil, an endless stainless belt, a stainless drum, or the like is suitably used. In the step ii), the conditions for drying (heating) the coating film are set according to the ultimately obtained film thickness and the production speed, and the dried polyamide acid film (gel film) is peeled off from the support. The drying temperature for the coating film is, for example, 50° C. or higher and 200° C. or lower. The drying time for drying of the coating film is, for example, 1 minute or more and 100 minutes or less.

Subsequently, in the step iii), for example, while the ends of the gel film are fixed to avoid shrinkage during curing, heating treatment is performed to remove water, the remaining solvent, the imidization accelerator, and the like from the gel film, and the remaining polyamide acid (1) is completely imidized to obtain a non-thermoplastic polyimide film containing a non-thermoplastic polyimide. The heating conditions are appropriately set according to the ultimately obtained film thickness and the production speed. As the heating conditions in the step iii), the maximum temperature is, for example, 370° C. or higher and 420° C. or lower, and the heating time at the maximum temperature is, for example, 10 seconds or more and 180 seconds or less. The temperature may be held at any temperature for any period of time until reaching the maximum temperature. The step iii) may be performed in air, under reduced pressure, or in an inert gas such as nitrogen. The heater usable in the step iii) is not particularly limited, and examples of the heater include hot air circulation ovens and far infrared ray ovens.

The non-thermoplastic polyimide film thus obtained can have a reduced dielectric loss tangent, and is therefore suitable for, for example, a material of a high-frequency circuit substrate (more specifically, a core layer of a multi-layered polyimide film, an insulating layer of a metal-clad laminate, or the like).

### [Physical Properties of Non-Thermoplastic Polyimide Film]

For reducing the transmission loss, the relative dielectric constant of the non-thermoplastic polyimide film is preferably 3.70 or less. For reducing the transmission loss, the dielectric loss tangent of the non-thermoplastic polyimide film is preferably 0.0050 or less, more preferably 0.0040 or less, and still more preferably 0.0030 or less.

For suppressing occurrence of internal stress in use in an FPC, the linear expansion coefficient of the non-thermoplastic polyimide film is preferably 25 ppm/K or less, more preferably 18 ppm/K or less, and still more preferably 16 ppm/K or less.

The thickness of the non-thermoplastic polyimide film is not particularly limited, and is, for example, 5 μm or more and 50 μm or less. The thickness of the non-thermoplastic polyimide film can be measured by using a laser hologage.

### Fourth Embodiment: Multi-Layered Polyimide Film

Next, a multi-layered polyimide film according to a fourth embodiment of the present invention will be described. The multi-layered polyimide film according to the fourth embodiment includes the non-thermoplastic polyimide film according to the third embodiment and an adhesive layer containing a thermoplastic polyimide. In the following description, description of contents overlapping with the contents of the first to the third embodiments may be omitted.

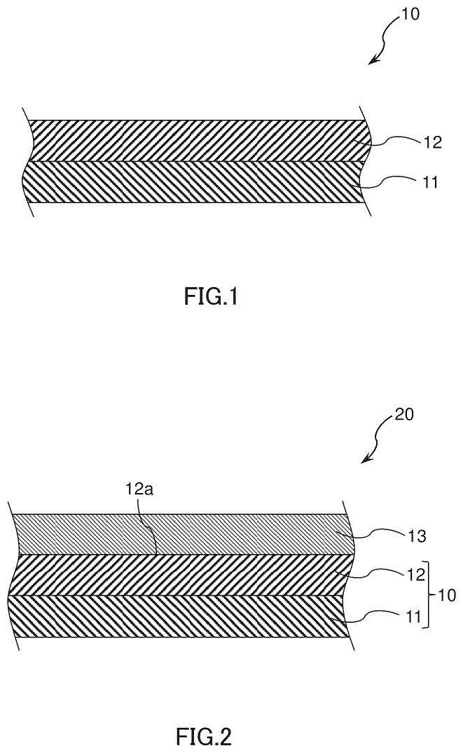

FIG. 1 is a sectional view showing an example of the multi-layered polyimide film according to the fourth embodiment. As shown in FIG. 1,a multi-layered polyimide film 10 includes a non-thermoplastic polyimide film 11 and an adhesive layer 12 disposed on at least one surface (one main surface) of the non-thermoplastic polyimide film 11 and containing a thermoplastic polyimide.

In the multi-layered polyimide film 10 shown in FIG. 1,the adhesive layer 12 is provided only on one surface of the non-thermoplastic polyimide film 11,but the adhesive layer 12 may be provided on each of both surfaces (both main surfaces) of the non-thermoplastic polyimide film 11. In a case where the adhesive layer 12 is provided on each of both surfaces of the non-thermoplastic polyimide film 11,the two adhesive layers 12 may contain the same kind of polyimide or different kinds of polyimides from each other. The thicknesses of the two adhesive layers 12 may be the same or different. In the following description, the “multi-layered polyimide film 10” includes a film including the adhesive layer 12 provided only on one surface of the non-thermoplastic polyimide film 11 and a film including the adhesive layer 12 provided on each of both surfaces of the non-thermoplastic polyimide film 11.

The thickness of the multi-layered polyimide film 10 (total thickness of the layers) is, for example, 6 μm or more and 60 μm or less. The thinner the thickness of the multi-layered polyimide film 10 is, the easier the weight reduction of the obtained FPC is, and the more improved the bendability of the obtained FPC is. For the easy weight reduction of the FPC with securing the mechanical strength and for the improvement in bendability of the FPC, the thickness of the multi-layered polyimide film 10 is preferably 7 μm or more and 60 μm or less, and more preferably 10 μm or more and 60 μm or less. The thickness of the multi-layered polyimide film 10 can be measured by using a laser hologage.

For easy achievement of the thickness reduction of the FPC with securing the adhesion to a metal foil, the thickness of the adhesive layer 12 (thickness of each adhesive layer 12 in a case where two adhesive layers 12 are provided) is preferably 1 μm or more and 15 μm or less.

For easy adjustment of the linear expansion coefficient of the multi-layered polyimide film 10, the thickness ratio between the non-thermoplastic polyimide film 11 and the adhesive layer 12 (thickness of non-thermoplastic polyimide film 11/thickness of adhesive layer 12) is preferably 55/45 or more and 95/5 or less. In a case where two adhesive layers 12 are provided, the thickness of the adhesive layer 12 used for calculating the thickness ratio is the total thickness of the adhesive layers 12.

For suppressing warpage of the multi-layered polyimide film 10, the adhesive layer 12 is preferably provided on each of both surfaces of the non-thermoplastic polyimide film 11,and the adhesive layers 12 containing the same kind of polyimide are preferably provided on both surfaces of the non-thermoplastic polyimide film 11. In a case where the adhesive layer 12 is provided on each of both surfaces of the non-thermoplastic polyimide film 11,the thicknesses of the two adhesive layers 12 are preferably the same for suppressing warpage of the multi-layered polyimide film 10. Even in a case where the thicknesses of the two adhesive layers 12 are different from each other, warpage of the multi-layered polyimide film 10 can be suppressed if the thickness of the thinner adhesive layer 12 is in the range of 40% or more and less than 100% based on the thickness of the thicker adhesive layer 12.

### [Adhesive Layer 12]

The thermoplastic polyimide contained in the adhesive layer 12 has an acid dianhydride residue and a diamine residue. Examples of the acid dianhydride (monomer) for formation of the acid dianhydride residue in the thermoplastic polyimide include the same compound as the acid dianhydride (monomer) for formation of the acid dianhydride residue in the non-thermoplastic polyimide described above. The kind of the acid dianhydride residue of the thermoplastic polyimide and the kind of the acid dianhydride residue of the non-thermoplastic polyimide may be the same or different.

For securing the thermoplasticity, the diamine residue of the thermoplastic polyimide is preferably a diamine residue having a bend structure. For more easily securing the thermoplasticity, the content rate of the diamine residue having a bend structure is preferably 50 mol % or more, more preferably 70 mol % or more, and still more preferably 80 mol % or more, and may be 100 mol % with respect to all of the diamine residues included in the thermoplastic polyimide. Examples of the diamine (monomer) for formation of the diamine residue having a bend structure include 4,4′-bis(4-aminophenoxy) biphenyl, 4,4′-bis(3-aminophenoxy) biphenyl, 1,3-bis(3-aminophenoxy)benzene, TPE-R, and 2,2-bis [4-(4-aminophenoxy)phenyl]propane (hereinafter, sometimes referred to as “BAPP”). For more easily securing the thermoplasticity, the diamine residue of the thermoplastic polyimide is preferably a BAPP residue.

For obtaining the adhesive layer 12 excellent in adhesion to a metal foil, the thermoplastic polyimide preferably has one or more selected from the group consisting of a BPDA residue and a PMDA residue, and a BAPP residue.

The adhesive layer 12 may contain a component (additive) other than the thermoplastic polyimide. As the additive, for example, a dye, a surfactant, a leveling agent, a plasticizer, silicone, a filler, a sensitizer, or the like can be used. The content rate of the thermoplastic polyimide in the adhesive layer 12 is, for example, 70 wt % or more, preferably 80 wt % or more, and more preferably 90 wt % or more, and may be 100 wt % with respect to the total amount of the adhesive layer 12.

### (Method for Forming Adhesive Layer 12)

The adhesive layer 12 is formed by, for example, applying a polyamide acid solution containing a polyamide acid as a precursor of a thermoplastic polyimide (hereinafter, sometimes referred to as “thermoplastic polyamide acid solution”) to at least one surface of the non-thermoplastic polyimide film 11,and then performing heating (drying and imidization of the polyamide acid). By this method, the multi-layered polyimide film 10 is obtained that includes the non-thermoplastic polyimide film 11 and the adhesive layer 12 disposed on at least one surface of the non-thermoplastic polyimide film 11. Instead of the thermoplastic polyamide acid solution, a solution containing a thermoplastic polyimide (thermoplastic polyimide solution) may be used to form a coating film of the thermoplastic polyimide solution on at least one surface of the non-thermoplastic polyimide film 11,and the coating film may be dried to form the adhesive layer 12.

Alternatively, for example, a laminate including a layer containing a polyamide acid as a precursor of the non-thermoplastic polyimide in the non-thermoplastic polyimide film 11 and a layer containing a polyamide acid as a precursor of a thermoplastic polyimide may be formed on a support by using a coextrusion die, and the obtained laminate may be heated to form the non-thermoplastic polyimide film 11 and the adhesive layer 12 at the same time. In this method, a metal foil is used as the support, and thus a metal-clad laminate (laminate of the multi-layered polyimide film 10 and the metal foil) is obtained simultaneously with completion of the imidization.

In the case of producing the multi-layered polyimide film 10 including three polyimide layers, a method is suitably used in which the application step and the heating step described above are repeated a plurality of times, or a plurality of coating films are formed by co-extrusion or continuous application (continuous casting) and heated at a time. Various surface treatments such as a corona treatment and a plasma treatment can also be performed on the outermost surface of the multi-layered polyimide film 10.

### Fifth Embodiment: Metal-Clad Laminate

Next, a metal-clad laminate according to a fifth embodiment of the present invention will be described. The metal-clad laminate according to the fifth embodiment includes the multi-layered polyimide film according to the fourth embodiment and a metal layer disposed on a main surface of at least one of the adhesive layer of the multi-layered polyimide film. In the following description, description of contents overlapping with the contents of the first to the fourth embodiments may be omitted.

FIG. 2 is a sectional view showing an example of the metal-clad laminate according to the fifth embodiment. As shown in FIG. 2, a metal-clad laminate 20 includes the multi-layered polyimide film 10 and a metal layer 13 (metal foil) disposed on a main surface 12a of the adhesive layer 12 of the multi-layered polyimide film 10.

### [Method for Producing Metal-Clad Laminate 20]

In production of the metal-clad laminate 20 by use of the multi-layered polyimide film 10, a metal foil as the metal layer 13 is bonded to at least one surface of the multi-layered polyimide film 10 (for example, in FIG. 2, the main surface 12a of the adhesive layer 12 on a side opposite from the non-thermoplastic polyimide film 11 side). In this way, the metal-clad laminate 20 shown in FIG. 2 is obtained. The method for bonding a metal foil to the main surface 12a of the adhesive layer 12 is not particularly limited, and various known methods can be adopted. For example, a continuous processing method can be adopted in which a hot-roll lamination apparatus having one or more pairs of metal rolls, or a double belt press (DBP) is used. The specific configuration of the means for hot-roll lamination is not particularly limited, and for improving the appearance of the obtained metal-clad laminate 20, a protective material is preferably disposed between the pressed surface and the metal foil.

In a case where the adhesive layer 12 is provided on each of both surfaces of the non-thermoplastic polyimide film 11,the metal foil is bonded to each of both surfaces (both main surfaces) of the multi-layered polyimide film 10 to obtain a double-sided metal-clad laminate (not shown).

The metal foil as the metal layer 13 is not particularly limited, and any metal foil can be used. For example, a metal foil is suitably used that includes any of copper, stainless steel, nickel, aluminum, alloys of these metals, and the like as a material. In general metal-clad laminates, a copper foil such as a rolled copper foil or an electrolytic copper foil is often used, and also in the fifth embodiment, a copper foil is preferably used. As the metal foil, a metal foil can be used that is subjected to a surface treatment or the like to adjust the surface roughness or the like according to the purpose. Furthermore, a rustproof layer, a heat resistant layer, an adhesive layer, and the like may be formed on the surface of the metal foil. The thickness of the metal foil is not particularly limited, and may be any thickness as long as a sufficient function can be exhibited according to the application. For easy achievement of the thickness reduction of the FPC with suppressing generation of creases in bonding to the multi-layered polyimide film 10, the thickness of the metal foil is preferably 5 μm or more and 50 μm or less.

### EXAMPLES

Hereinafter, one or more embodiments of the present invention will be specifically described with reference to examples, but the present invention is not limited to these examples.

### <Method for Measuring Physical Properties>

First, the methods for measuring the relative dielectric constant, the dielectric loss tangent, and the linear expansion coefficient of the polyimide film will be described.

### [Relative Dielectric Constant and Dielectric Loss Tangent]

The relative dielectric constant and the dielectric loss tangent of the polyimide film were measured with a network analyzer (“8719 C” manufactured by Hewlett-Packard Company) and a cavity resonator perturbation dielectric constant measurement apparatus (“CP531” manufactured by EM labs, Inc.). Specifically, first, the polyimide film was cut into 2 mm×100 mm to prepare a sample for measurement of the relative dielectric constant and the dielectric loss tangent. Subsequently, the sample for measurement was left standing in an atmosphere at a temperature of 23° C. and a relative humidity of 50% for 24 hours, and then the relative dielectric constant and the dielectric loss tangent were measured under the conditions of a temperature of 23° C., a relative humidity of 50%, and a measurement frequency of 10 GHz by using the network analyzer and the cavity resonator perturbation dielectric constant measurement apparatus. In a case where the dielectric loss tangent was 0.0030 or less, evaluation “the dielectric loss tangent can be reduced” was given. In a case where the dielectric loss tangent was more than 0.0030, evaluation “the dielectric loss tangent cannot be reduced” was given.

### [Linear Expansion Coefficient (CTE)]

By using a thermal analyzer (“TMA/SS6100” manufactured by Hitachi High-Tech Science Corporation), a polyimide film (sample) was heated from −10° C. to 300° C. under a condition of a temperature rise rate of 10° C./min, and then cooled to −10° C. at a temperature decrease rate of 40° C./min. Subsequently, the sample was heated again to 300° C. under the condition of a temperature rise rate of 10° C./min, and the linear expansion coefficient was determined from the strain amount at 50° C. to 250° C. during the second temperature rise. The measurement conditions are shown below.
Size of sample (polyimide film): 3 mm in width and 10 mm in length
Load: 1 g
Measurement atmosphere: air atmosphere

### <Preparation of Polyimide Film>

Hereinafter, the methods for preparing a polyimide film in examples and comparative examples will be described. In the following, compounds and reagents are represented by the following abbreviations. The polyamide acid solutions for use in preparation of the polyimide films were each prepared in a nitrogen atmosphere at a temperature of 20° C.
DMF: N,N-dimethylformamide
PDA: p-phenylenediamine
TPE-R: 1,3-bis(4-aminophenoxy)benzene
BAPP: 2,2-bis [4-(4-aminophenoxy)phenyl]propane
BPDA: 3,3′,4,4′-biphenyltetracarboxylic dianhydride
PMDA: pyromellitic dianhydride
BTDA: 3,3′,4,4′-benzophenonetetracarboxylic dianhydride
ODPA: 4,4′-oxydiphthalic anhydride
AA: acetic anhydride
IQ: isoquinoline

### Example 1

### (First Sequence Polymerization Step)

Into a glass flask having a volume of 2000 mL, 314.58 g of DMF and 10.11 g of PDA were put, and then 16.25 g of BPDA, 1.54 g of PMDA, and 8.67 g of BTDA were put into the flask while the flask contents were stirred. Subsequently, the flask contents were stirred for 30 minutes.

### (Second Sequence Polymerization Step)

Then, while the flask contents were stirred, 16.85 g of a PDA solution prepared in advance (solvent: DMF, PDA concentration: 20 wt %) and 4.97 g of TPE-R were gradually added in the flask. After visually confirming dissolution of the TPE-R, 14.17 g of BPDA was added in the flask while the flask contents were stirred, and the flask contents were stirred for 30 minutes. Subsequently, a PMDA solution prepared in advance (solvent: DMF, amount of dissolved PMDA: 0.93 g, PMDA concentration: 7.2 wt %) was continuously added in the flask for a predetermined time at an addition rate such that the viscosity of the flask contents did not rapidly increase. At the time when the viscosity of the flask contents at a temperature of 23° C. reached 1500 poises, the addition of the PMDA solution was stopped, and the flask contents were further stirred for 1 hour to obtain a polyamide acid solution. The obtained polyamide acid solution had a solid content concentration of 15 wt %. The obtained polyamide acid solution had a viscosity of 1500 to 2000 poises at a temperature of 23° C.

### (Film Formation Step)

Subsequently, 27.5 g of an imidization accelerator including a mixture of AA, IQ, and DMF (weight ratio: AA/IQ/DMF=42/21/37) was added to 55 g of the polyamide acid solution (polyamide acid solution obtained by the above-described preparation method) to prepare a dope solution. Subsequently, the dope solution was defoamed while stirred in an atmosphere at a temperature of 0° C. or lower, and then the dope solution was applied onto an aluminum foil with a Comma Coater to form a coating film. Subsequently, the coating film was heated at a heating temperature of 110° C. for 160 seconds to obtain a self-supporting gel film. The obtained gel film was peeled off from the aluminum foil, fixed to a metallic fixation frame, put into a hot air circulation oven preheated to a temperature of 300° C., and heated at a heating temperature of 300° C. for 56 seconds. Subsequently, the heated film was put into a far infrared (IR) oven preheated to a temperature of 380° C., and heated at a heating temperature of 380° C. for 49 seconds to imidize the polyamide acid in the gel film, and then the resulting film was separated from the metallic fixation frame to obtain a polyimide film (thickness: 17 μm) of Example 1.

When a polyimide film obtained in the same procedure as described above was fixed to a metallic fixation frame and heated at a heating temperature of 380° C. for 1 minute using an IR oven, the polyimide film retained its shape (film shape). Therefore, the polyimide contained in the polyimide film of Example 1 was a non-thermoplastic polyimide. That is, the polyimide film of Example 1 was a non-thermoplastic polyimide film. As for the polyimide films of Examples 2 to 12 described below, when a polyimide film obtained in the same procedure as described below was fixed to a metallic fixation frame and heated at a heating temperature of 380° C. for 1 minute using an IR oven, the polyimide film also retained its shape (film shape). Therefore, all of the polyimides contained in the polyimide films of Examples 2 to 12 were a non-thermoplastic polyimide. That is, all of the polyimide films of Examples 2 to 12 were a non-thermoplastic polyimide film.

### Examples 2 to 12

Polyimide films of Examples 2 to 12 (each having a thickness of 17 μm) were obtained with the same method as in Example 1 except that the kinds of the monomers used in the first sequence polymerization step, the ratio (addition ratio) between the monomers in the first sequence polymerization step, the kinds of the monomers used in the second sequence polymerization step, and the ratio (addition ratio) between the monomers in the second sequence polymerization step were set as shown in Tables 1 and 2 below. The total substance amount of the acid dianhydrides and the diamines in each of Examples 2 to 12 was the same as that in Example 1.

### Comparative Example 1

A polyimide film of Comparative Example 1 (having a thickness of 17 μm) was obtained with the same method as in Example 1 except that the first sequence polymerization step and the second sequence polymerization step were changed as follows.

### First Sequence Polymerization Step in Comparative Example 1

Into a glass flask having a volume of 2000 mL, 315.40 g of DMF and 9.78 g of PDA were put, and then 15.72 g of BPDA, 1.49 g of PMDA, and 8.39 g of BTDA were put into the flask while the flask contents were stirred. Subsequently, the flask contents were stirred for 30 minutes.

### Second Sequence Polymerization Step in Comparative Example 1

Then, while the flask contents were stirred, 16.30 g of a PDA solution prepared in advance (solvent: DMF, PDA concentration: 20 wt %) and 6.75 g of BAPP were gradually added in the flask. After visually confirming dissolution of the BAPP, 13.71 g of BPDA was added in the flask while the flask contents were stirred, and the flask contents were stirred for 30 minutes. Subsequently, a PMDA solution prepared in advance (solvent: DMF, amount of dissolved PMDA: 0.90 g, PMDA concentration: 7.2 wt %) was continuously added in the flask for a predetermined time at an addition rate such that the viscosity of the flask contents did not rapidly increase. At the time when the viscosity of the flask contents at a temperature of 23° C. reached 1500 poises, the addition of the PMDA solution was stopped, and the flask contents were further stirred for 1 hour to obtain a polyamide acid solution. The obtained polyamide acid solution had a solid content concentration of 15 wt %. The obtained polyamide acid solution had a viscosity of 1500 to 2000 poises at a temperature of 23° C.

### Comparative Example 2

A polyimide film of Comparative Example 2 (having a thickness of 17 μm) was obtained with the same method as in Example 1 except that the polyamide acid solution was prepared with the following method (random polymerization).

### Method for Preparing Polyamide Acid Solution of Comparative Example 2

Into a glass flask having a volume of 500 mL, 165.61 g of DMF, 2.08 g of TPE-R, and 6.71 g of PDA were put, and then 20.98 g of BPDA was put into the flask while the flask contents were stirred. Then, the flask contents were stirred for 60 minutes to obtain a polyamide acid solution. The obtained polyamide acid solution had a solid content concentration of 15 wt %. The obtained polyamide acid solution had a viscosity of 1500 poises at a temperature of 23° C.

### Comparative Example 3

A polyimide film of Comparative Example 3 (having a thickness of 17 μm) was obtained with the same method as in Example 1 except that the polyamide acid solution was prepared with the following method (random polymerization).

### Method for Preparing Polyamide Acid Solution of Comparative Example 3

Into a glass flask having a volume of 500 mL, 160.84 g of DMF and 7.95 g of PDA were put, and then 17.31 g of BPDA and 4.03 g of BTDA were put into the flask while the flask contents were stirred. Subsequently, the flask contents were stirred for 30 minutes. Subsequently, a BTDA solution prepared in advance (solvent: DMF, amount of dissolved BTDA: 0.71 g, BTDA concentration: 7.2 wt %) was continuously added in the flask for a predetermined time at an addition rate such that the viscosity of the flask contents did not rapidly increase. At the time when the viscosity of the flask contents at a temperature of 23° C. reached 1500 poises, the addition of the BTDA solution was stopped, and the flask contents were further stirred for 1 hour to obtain a polyamide acid solution. The obtained polyamide acid solution had a solid content concentration of 15 wt %. The obtained polyamide acid solution had a viscosity of 1500 to 2000 poises at a temperature of 23° C.

### Comparative Example 4

A polyimide film of Comparative Example 4 (having a thickness of 17 μm) was obtained with the same method as in Example 1 except that the polyamide acid solution was prepared with the following method (random polymerization).

### Method for Preparing Polyamide Acid Solution of Comparative Example 4

Into a glass flask having a volume of 500 mL, 163.95 g of DMF, 6.59 g of PDA, and 3.14 g of TPE-R were put, and then 15.57 g of ODPA and 4.22 g of PMDA were put into the flask while the flask contents were stirred. Subsequently, the flask contents were stirred for 30 minutes. Subsequently, a PMDA solution prepared in advance (solvent: DMF, amount of dissolved PMDA: 0.47 g, PMDA concentration: 7.2 wt %) was continuously added in the flask for a predetermined time at an addition rate such that the viscosity of the flask contents did not rapidly increase. At the time when the viscosity of the flask contents at a temperature of 23° C. reached 1500 poises, the addition of the PMDA solution was stopped, and the flask contents were further stirred for 1 hour to obtain a polyamide acid solution. The obtained polyamide acid solution had a solid content concentration of 15 wt %. The obtained polyamide acid solution had a viscosity of 1500 to 2000 poises at a temperature of 23° C.

### Comparative Example 5

A polyimide film of Comparative Example 5 (having a thickness of 17 μm) was obtained with the same method as in Example 1 except that the polyamide acid solution was prepared with the following method (random polymerization).

### Method for Preparing Polyamide Acid Solution of Comparative Example 5

Into a glass flask having a volume of 500 mL, 163.88 g of DMF, 7.07 g of PDA, and 2.12 g of TPE-R were put, and then 19.23 g of BPDA and 1.11 g of PMDA were put into the flask while the flask contents were stirred. Subsequently, the flask contents were stirred for 30 minutes. Subsequently, a PMDA solution prepared in advance (solvent: DMF, amount of dissolved PMDA: 0.48 g, PMDA concentration: 7.2 wt %) was continuously added in the flask for a predetermined time at an addition rate such that the viscosity of the flask contents did not rapidly increase. At the time when the viscosity of the flask contents at a temperature of 23° C. reached 1500 poises, the addition of the PMDA solution was stopped, and the flask contents were further stirred for 1 hour to obtain a polyamide acid solution. The obtained polyamide acid solution had a solid content concentration of 15 wt %. The obtained polyamide acid solution had a viscosity of 1500 to 2000 poises at a temperature of 23° C.

### <Results>

Tables 1 and 2 show, for Examples 1 to 12 and Comparative Examples 1 to 5, the kinds of the monomers used in the first sequence polymerization step, the ratio (addition ratio) between the monomers in the first sequence polymerization step, the kinds of the monomers used in the second sequence polymerization step, the ratio (addition ratio) between the monomers in the second sequence polymerization step, the relative dielectric constant, the dielectric loss tangent, and the CTE.

In Tables 1 to 2, “1st” and “2nd” mean the “first sequence polymerization step” and the “second sequence polymerization step”, respectively. For Comparative Examples 2 to 5, random polymerization was performed, and therefore the kinds of the monomers used and the ratio (addition ratio) between the monomers are described in the column of “1st”.

In Tables 1 and 2, a numerical value in the column of “Diamine” is the content rate (unit: mol %) of each diamine to the total amount of the diamines used (in the case of sequence polymerization, the sum of the total amount of the diamines used in the first sequence polymerization step and the total amount of the diamines used in the second sequence polymerization step). In Tables 1 and 2, a numerical value in the column of “Acid dianhydride” is the content rate (unit: mol %) of each acid dianhydride to the total amount of the acid dianhydrides used (in the case of sequence polymerization, the sum of the total amount of the acid dianhydrides used in the first sequence polymerization step and the total amount of the acid dianhydrides used in the second sequence polymerization step).

In each of Examples 1 to 12 and Comparative Examples 1 to 5, the molar fraction of each residue in the polyamide acid contained in the prepared polyamide acid solution was equal to the molar fraction of each monomer (each of the diamines and the tetracarboxylic dianhydrides) used. In each of Examples 1 to 12 and Comparative Examples 1 to 5, the substance amount ratio obtained by dividing the total substance amount of the tetracarboxylic dianhydride residues included in the polyimide contained in the obtained polyimide film by the total substance amount of the diamine residues included in the polyimide was 0.99 or more and 1.01 or less. In Table 2, “-” in the column of CTE means that measurement was not performed.

TABLE 1

| | | Diamine | | | | | | | Relative | Dielectric | |
|---|---|---|---|---|---|---|---|---|---|---|---|
| | | [mol %] | | | Acid dianhydride [mol %] | | | | dielectric | loss | CTE |
| | | PDA | TPE-R | BAPP | BPDA | PMDA | BTDA | ODPA | constant | tangent | [ppm/K] |
| Example | 1st | 66 | 0 | 0 | 39 | 5 | 19 | 0 | 3.59 | 0.0028 | 8.4 |
| 1 | 2nd | 22 | 12 | 0 | 34 | 3 | 0 | 0 | | | |
| Example | 1st | 62 | 4 | 0 | 39 | 5 | 19 | 0 | 3.69 | 0.0029 | 10.3 |
| 2 | 2nd | 22 | 12 | 0 | 34 | 3 | 0 | 0 | | | |
| Example | 1st | 64 | 2 | 0 | 39 | 5 | 19 | 0 | 3.60 | 0.0028 | 9.4 |
| 3 | 2nd | 22 | 12 | 0 | 34 | 3 | 0 | 0 | | | |
| Example | 1st | 64 | 2 | 0 | 39 | 5 | 19 | 0 | 3.31 | 0.0029 | 9.1 |
| 4 | 2nd | 24 | 10 | 0 | 34 | 3 | 0 | 0 | | | |
| Example | 1st | 66 | 2 | 0 | 41 | 5 | 19 | 0 | 3.32 | 0.0029 | 8.3 |
| 5 | 2nd | 22 | 10 | 0 | 32 | 3 | 0 | 0 | | | |
| Example | 1st | 66 | 2 | 0 | 41 | 5 | 19 | 0 | 3.34 | 0.0029 | 10.4 |
| 6 | 2nd | 20 | 12 | 0 | 32 | 3 | 0 | 0 | | | |
| Example | 1st | 66 | 2 | 0 | 44 | 5 | 16 | 0 | 3.32 | 0.0029 | 8.7 |
| 7 | 2nd | 20 | 12 | 0 | 32 | 3 | 0 | 0 | | | |
| Example | 1st | 66 | 2 | 0 | 37 | 5 | 23 | 0 | 3.35 | 0.0030 | 9.1 |
| 8 | 2nd | 20 | 12 | 0 | 32 | 3 | 0 | 0 | | | |
| Example | 1st | 66 | 2 | 0 | 41 | 5 | 19 | 0 | 3.30 | 0.0030 | 11.5 |
| 9 | 2nd | 18 | 14 | 0 | 32 | 3 | 0 | 0 | | | |
| Example | 1st | 64 | 4 | 0 | 41 | 5 | 19 | 0 | 3.29 | 0.0028 | 12.5 |
| 10 | 2nd | 20 | 12 | 0 | 32 | 3 | 0 | 0 | | | |

TABLE 2

| | | Diamine | | | | | | | Relative | Dielectric | |
|---|---|---|---|---|---|---|---|---|---|---|---|
| | | [mol %] | | | Acid dianhydride [mol %] | | | | dielectric | loss | CTE |
| | | PDA | TPE-R | BAPP | BPDA | PMDA | BTDA | ODPA | constant | tangent | [ppm/K] |
| Example 11 | 1st | 66 | 2 | 0 | 43 | 3 | 19 | 0 | 3.30 | 0.0029 | 10.5 |
| | 2nd | 20 | 12 | 0 | 32 | 3 | 0 | 0 | | | |
| Example 12 | 1st | 66 | 2 | 0 | 39 | 7 | 19 | 0 | 3.29 | 0.0029 | 9.8 |
| | 2nd | 20 | 12 | 0 | 32 | 3 | 0 | 0 | | | |
| Comparative | 1st | 66 | 0 | 0 | 39 | 5 | 19 | 0 | 3.35 | 0.0041 | 7.3 |
| Example 1 | 2nd | 22 | 0 | 1 | 34 | 3 | 0 | 0 | | | |
| | | | | 2 | | | | | | | |
| Comparative | 1st | 90 | 10 | 0 | 100 | 0 | 0 | 0 | 3.57 | 0.0053 | — |
| Example 2 | | | | | | | | | | | |
| Comparative | 1st | 10 | 0 | 0 | 80 | 0 | 20 | 0 | 3.54 | 0.0038 | — |
| Example 3 | | 0 | | | | | | | | | |
| Comparative | 1st | 85 | 15 | 0 | 0 | 30 | 0 | 70 | 3.53 | 0.0064 | — |
| Example 4 | | | | | | | | | | | |
| Comparative | 1st | 90 | 10 | 0 | 90 | 10 | 0 | 0 | 3.45 | 0.0043 | — |
| Example 5 | | | | | | | | | | | |

The polyamide acid contained in the polyamide acid solution prepared in each of Examples 1 to 12 had a BPDA residue, a BTDA residue, a PDA residue, and a TPE-R residue.

In Examples 1 to 12, the dielectric loss tangent was 0.0030 or less. Thus, in the polyimide films of Examples 1 to 12, reduction of the dielectric loss tangent was achieved.

The polyamide acid contained in the polyamide acid solution prepared in each of Comparative Examples 1 and 3 did not have a TPE-R residue. The polyamide acid contained in the polyamide acid solution prepared in each of Comparative Examples 2, 4, and 5 did not have a BTDA residue. The polyamide acid contained in the polyamide acid solution prepared in Comparative Example 4 did not have a BPDA residue.

In Comparative Examples 1 to 5, the dielectric loss tangent was more than 0.0030. Thus, in the polyimide films of Comparative Examples 1 to 5, reduction of the dielectric loss tangent was not achieved.

From the above results, it has been shown that according to one or more embodiments of the present invention, a non-thermoplastic polyimide film can be provided in which the dielectric loss tangent can be reduced.

Although the disclosure has been described with respect to only a limited number of embodiments, those skilled in the art, having benefit of this disclosure, will appreciate that various other embodiments may be devised without departing from the scope of the present disclosure. Accordingly, the scope of the invention should be limited only by the attached claims.

### DESCRIPTION OF REFERENCE SIGNS

10 multi-layered polyimide film
11 non-thermoplastic polyimide film
12 adhesive layer
13 metal layer
20 metal-clad laminate

1. A polyamide acid comprising:
tetracarboxylic dianhydride residues; and
diamine residues,
wherein the tetracarboxylic dianhydride residues comprise a 3,3′, 4,4′-biphenyltetracarboxylic dianhydride residue and a 3,3′, 4,4′-benzophenonetetracarboxylic dianhydride residue,
wherein the diamine residues comprise a p-phenylenediamine residue and a 1,3-bis(4-aminophenoxy)benzene residue,
wherein a content rate of the 3,3′, 4,4′-biphenyltetracarboxylic dianhydride residue is 55 mol % or more and 85 mol % or less with respect to a total amount of the tetracarboxylic dianhydride residues, and
wherein a content rate of the 3,3′, 4,4′-benzophenonetetracarboxylic dianhydride residue is 10 mol % or more and 30 mol % or less with respect to the total amount of the tetracarboxylic dianhydride residues.

2. The polyamide acid according to claim 1,wherein a content rate of the p-phenylenediamine residue is 75 mol % or more and 95 mol % or less with respect to a total amount of the diamine residues.

3. The polyamide acid according to claim 1,wherein
the tetracarboxylic dianhydride residues further comprises a pyromellitic dianhydride residue, and
a content rate of the pyromellitic dianhydride residue is 3 mol % or more and 15 mol % or less with respect to the total amount of the tetracarboxylic dianhydride residues.

4. A polyimide that is an imidized product of the polyamide acid according to claim 1.

5. A non-thermoplastic polyimide film comprising the polyimide according to claim 4.

6. A multi-layered polyimide film comprising:
the non-thermoplastic polyimide film according to claim 5; and
an adhesive layer disposed on at least one surface of the non-thermoplastic polyimide film, the adhesive layer containing a thermoplastic polyimide.

7. The multi-layered polyimide film according to claim 6, wherein the adhesive layer is disposed on each of both surfaces of the non-thermoplastic polyimide film.

8. A metal-clad laminate comprising:
the multi-layered polyimide film according to claim 6; and
a metal layer disposed on a main surface of at least one of the adhesive layer of the multi-layered polyimide film.
